(19) United States
(12) Patent Application Publication
(10) Pub. No.: US 2017/0025203 A1
(43) Pub. Date: Jan. 26, 2017

(54) CABLE HAVING IMPROVED WIRES ARRANGEMENT

(71) Applicant: FOXCONN INTERCONNECT TECHNOLOGY LIMITED, Grand Cayman (KY)

(72) Inventors: ZU-XUAN CHEN, Huaian (CN); HONG-PING WANG, Huaian (CN); LU-YU CHANG, New Taipei (TW)

(21) Appl. No.: 15/215,859

(22) Filed: Jul. 21, 2016

(30) Foreign Application Priority Data
Jul. 22, 2015 (CN) 201520533889.X

(51) Int. Cl. H01B 11/00; H05K 9/00

(52) U.S. Cl. CPC H01B 11/002; H05K 9/0081; H05K 9/0088

(57) ABSTRACT

A cable (100) includes: plural centrally disposed first wires (1); an inner shielding layer (17) enclosing the first wires; plural second wires (2) disposed at an outer side of the inner shielding layer for transmitting a common power signal; and plural pairs of differential signal wires (3) disposed at the outer side of the inner shielding layer; wherein each pair of differential signal wires is disposed between two adjacent second wires.

### BACKGROUND OF THE INVENTION

1. Field of the Invention

The present invention relates to a cable, and more particularly to a cable used for USB type C.

2. Description of Related Arts

U.S. Patent Application Publication No. 2016/0079689, published on Mar. 17, 2016 to Wu et al., discloses a cable comprising a plurality of coaxial wires and a plurality of single core wires. Each of the coaxial wires comprises a central conductor, an insulator enclosing the central conductor, a shielding layer enclosing the insulator, and a jacket enclosing the shielding layer. The structure of the coaxial wires entails an expensive manufacturing process. The coaxial wires are so arranged side by side along a circular direction that cross talk between adjacent coaxial wires may occur under a high speed signal transmission.

U.S. Patent Application Publication No. 2010/0258333, published on Oct. 14, 2010 to Horan et al., discloses a high speed data cable with shield connection. A cross-sectional view of a raw high speed Universal Serial Bus (USB) cable disclosed therein shows a concentric ring arrangement of signal and ground wires. According to an embodiment, nine insulating wires are arranged as follows: a pair of insulated data signal wires D0+ and D0−; a first pair of insulated super-speed data signal wires S0+ and S0−; a second pair of insulated super-speed data signal wires S1+ and S1−; and three insulated ground wires, or ground conductors G0, G1, and G2.

USB Type-C Cable and Connector Specification Revision 1.0 published on Aug. 11, 2014, illustrates a high speed cable comprising a plurality of first wires (for USB 2.0 signaling, SBU1, SBU2, CC, power return, and Vconn), an inner shielding layer enclosing the first wires, a plurality of coaxial wires (differential pairs) for high speed signaling arranged at an outer side of the inner shielding, and a power wire disposed between the coaxial wires.

### SUMMARY OF THE INVENTION

An object of the present invention is to provide a cable having a simple structure, low cost, easy to manufacture, and improved high speed signal transmission performance.

To achieve the above-mentioned object, a cable comprises: a plurality of first wires centrally disposed; an inner shielding layer enclosing the first wires; a plurality of second wires disposed at an outer side of the inner shielding layer for transmitting a common power signal; and a plurality of pairs of differential signal wires disposed at the outer side of the inner shielding layer; wherein each pair of differential signal wires is disposed between two adjacent second wires.

### BRIEF DESCRIPTION OF THE DRAWING

FIG. 1 is a cross section view of a cable in accordance with present invention;

FIG. 2 is a cross section view of first wires of the cable as shown in FIG. 1; and

FIG. 3 is a cross section view of a pair of the differential wires of the cable as shown in FIG. 1.

### DETAILED DESCRIPTION OF THE PREFERRED EMBODIMENT

Reference will now be made in detail to a preferred embodiment of the present invention.

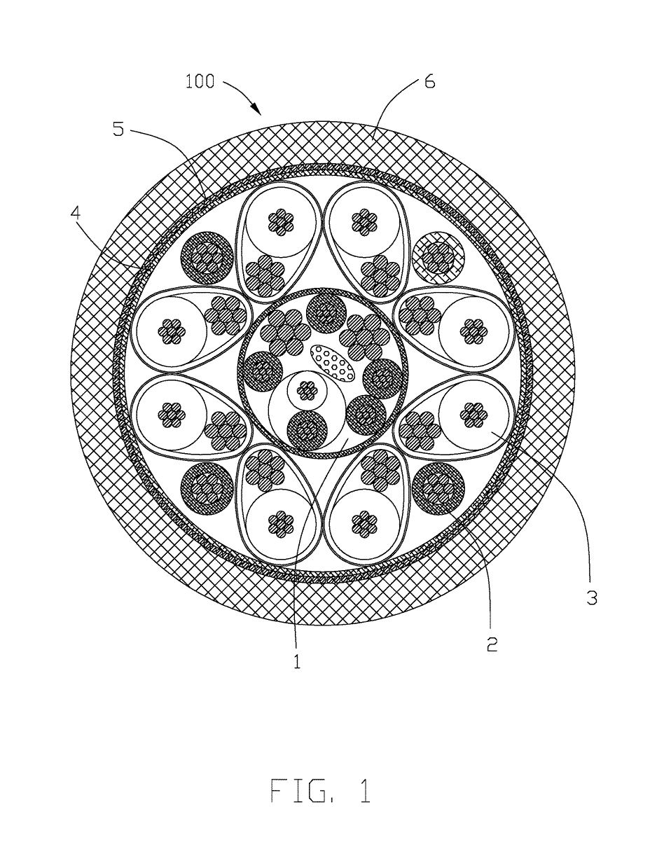

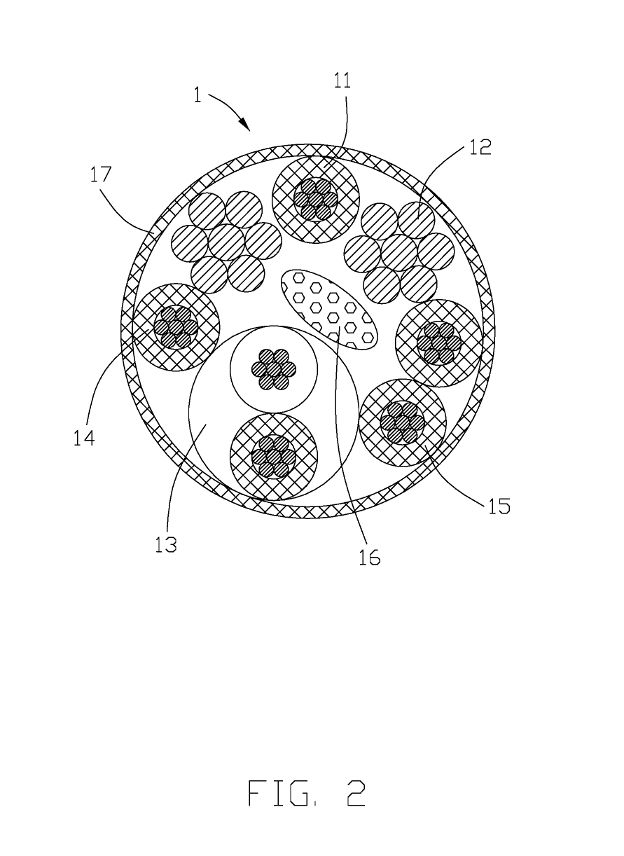

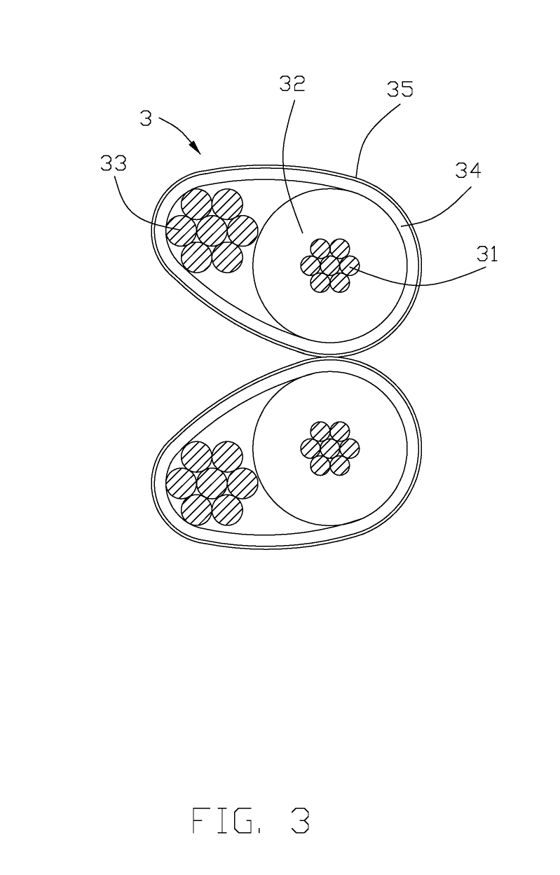

Referring to FIGS. 1 to 3, a cable 100 comprises a plurality of first wires 1 disposed at a central portion of the cable 100, a plurality of second wires 2 for transmitting a common power signal, a plurality of differential signal wire pairs 3 for transmitting high speed signal, a tap layer 4 enclosing the differential signal wires pairs 3 and the second wires 2, an outer shielding layer 5 enclosing the tap layer 4, and a jacket 6 enclosing the outer shielding layer 5. The tap layer 4 is formed by aluminum foil or polythylene terephthalate. The tap layer 4 can provide EMI shielding when the cable 1 is used to transmitting high frequency signal.

The second wires 2 and the differential signal wires pairs 3 are arranged at an outer side of the first wires 1 and spaced apart with each other. In this embodiment, the number of the differential signal wires pairs 3 is four, and the number of the second wires 2 is four. But, the number of the differential signal wires pairs 3 and the second wires 2 may be in accordance with the needed.

The first wires 1 comprises a pair of twist wires for transmitting USB 2.0 signal 13, a detection signal wire 11, a pair of power grounding wires 12 disposed at opposites of the detection signal wire 11, a power wire 15 disposed at a side of the twist wires 13, a pair of spare wires 14 disposed between the power grounding wires 12 and the twist wires 13 and the power wire respectively. The cable 100 further comprises a filler disposed at a central of the first wires 1 to fill the gap of the first wires 1. The spare wires 14 may be used for transmitting audio or video signal. The cable 100 comprises an inner shielding layer 17 enclosing the first wires 1. The inner shielding layer 17 is formed by aluminum foil or polythylene terephthalate. The inner shielding layer 17 may reduce a cross talk between the second wires 2 and the first wires 1.

The second wires 2 and the differential signal wire pairs 3 are disposed between the inner shielding layer 17 and the tap layer 4. Each pair of the differential signal wires pairs 3 is disposed between two adjacent of the second wires 2, respectively. Each of the differential signal wire pairs 3 comprises a central conductor 31 for transmitting signal, an insulator 32 enclosing the central conductor 31, a drain wire 33 disposed at an outer side of the insulator 32, a shielding layer 34 enclosing the drain wire 33 and the insulator 32, and a tap 35 enclosing the shielding layer 34. The drain wire 33 contacts and electrically connects with the shielding layer 34. The drain wire 33 has a diameter less than a diameter of the insulator 32. Both of the central conductor 31 and the drain wire comprise a plurality of conductors.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A cable comprising:
a plurality of first wires centrally disposed;
an inner shielding layer enclosing the first wires;
a plurality of second wires disposed at an outer side of the inner shielding layer for transmitting a common power signal; and
a plurality of pairs of differential signal wires disposed at the outer side of the inner shielding layer;
wherein each pair of differential signal wires is disposed between two adjacent second wires.

2. The cable as recited in claim 1, wherein each differential signal wire comprises a central conductor, an insulator enclosing the central conductor, a drain wire disposed at an outer side of the insulator, a shielding layer enclosing the drain wire and the insulator, and a tap enclosing the shielding layer.

3. The cable as recited in claim 2, wherein the drain wire has a diameter less than a diameter of the insulator.

4. The cable as recited in claim 2, wherein the drain wire contacts and electrically connects with the shielding layer.

5. The cable as recited in claim 2, wherein there are four pairs of differential signal wires and four second wires.

6. The cable as recited in claim 1 wherein the first wires comprise a pair of twist wires for transmitting USB 2.0 signal.

7. The cable as recited in claim 6, wherein the first wires comprise a detection signal wire, a pair of power grounding wires disposed at opposite sides of the detection signal wire, a power wire disposed at a side of the twist wires, and a pair of spare wires.

8. The cable as recited in claim 1, further comprising a tap layer enclosing the differential signal wires pairs and the second wires, an outer shielding layer enclosing the tap layer, and a jacket enclosing the outer shielding layer.

9. The cable as recited in claim 1, wherein each of the second wires has a diameter less than a diameter of each of the pair of differential signal wires.

10. A round cable comprising:
a plurality of first wires located at a center thereof and including at least three different type wires;
a plurality of second wires and a plurality of third wire pairs alternately along a periphery of the inner shielding layer in a surrounding manner; wherein
each of the third wire pair includes two differential-pair signal wires while each of the second wires is a power wire, and each of the two differential-pair signal wires is larger than each of the second wires in a cross-sectional view.

11. The round cable as claimed in claim 10, wherein each of said two differential-pair signal wires defines a tumbler configuration with a large bottom portion and a small top portion commonly surrounded within a shield layer in the cross-section view.

12. The round cable as claimed in claim 11, wherein in each third wire pair, the two top portions of said two differential-pair signal wires are spaced from each other while the two bottom portions thereof abut against each other.

13. The round cable as claimed in claim 12, wherein the top portion of each differential-pair signal wire closely abuts against the top portion of another differential-pair signal wire of a neighboring third wire pair while the bottom portion of said differential-pair signal wire is spaced from the bottom portion of said another differential-pair signal wire with a corresponding second wire therebetween.

14. The round cable as claimed in claim 11, wherein said top portion includes a drain wire contacting the shield layer, and the bottom portion includes a conductor enclosed within an inner insulator.

15. The round cable as claimed in claim 11, wherein each of said two differential-pair signal wires further includes a colorful layer surrounding the shield layer.

16. The round cable as claimed in claim 10, wherein said plurality of first wires are commonly enclosed within an inner shielding layer.

17. The round cable as claimed in claim 16, wherein the first wires include a power wire, a grounding wire, a detection wire, and two signal wires.

18. A round cable comprising:
a plurality of first wires located at a center thereof and including at least a power wire, a grounding wire, a signal detection wire and a pair of signal wires; and
a plurality of power wires and a plurality of differential-pair wire pairs alternately along a periphery of the inner shielding layer in a surrounding manner; wherein
each pair of the differential-pair wire pairs includes two differential-pair signal wires, each of the two differential-pair signal wires is larger than each of the second wires in a cross-sectional view.

19. The round cable as claimed in claim 19, wherein the first wires are commonly enclosed within an inner shielding layer.

20. The round cable as claimed in claim 19, wherein each of said two differential-pair signal wires defines a tumbler configuration with a large bottom portion and a small top portion commonly surrounded within a shield layer in the cross-section view, and the bottom portion includes a central conductor enclosed within an inner insulator, and the top portion includes a drain wire contacting the shield layer.
